(19) United States
(12) Patent Application Publication
(10) Pub. No.: US 2011/0254551 A1
(43) Pub. Date: Oct. 20, 2011

(54) GRADIENT COIL ASSEMBLY FOR MRI WITH INTEGRATED RF TRANSMIT AMPLIFIERS

(75) Inventor: Christoph Leussler, Hamburg (DE)

(73) Assignee: KONINKLIJKE PHILIPS ELECTRONICS N.V., EINDHOVEN (NL)

(21) Appl. No.: 13/141,093

(22) PCT Filed: Nov. 23, 2009
(86) PCT No.: PCT/IB2009/055296

§ 371 Date: Jun. 21, 2011

Related U.S. Application Data
(60) Provisional application No. 61/141,923, filed on Dec. 31, 2008.

(51) Int. Cl. G01R 33/44

(52) U.S. Cl. 324/318

(57) ABSTRACT

A magnetic field gradient coil assembly comprises: a structural former (20, 70, 90, 110); one or more magnetic field gradient coils (22, 24) disposed on or in the structural former; cooling conduits (52, 76, 92, 116) disposed on or in the structural former and configured to flow cooling fluid for removing heat generated by the one or more magnetic field gradient coils; and a radio frequency power amplifier (40, 42, 98) disposed on or in the structural former.

The following relates to the magnetic resonance arts, and will find illustrative application in magnetic resonance imaging, magnetic resonance spectroscopy, and related applications.

A typical magnetic resonance system includes a cylindrical main magnet generating a static (B₀) magnetic field in an axial or “z”-direction, and a generally cylindrical gradient coil assembly including a dielectric former supporting various conductive windings configured to superimpose selected magnetic field gradients on the static (B₀) magnetic field. Cooling lines disposed in or on the dielectric former provide cooling for the gradient coil assembly. Typically, water is used as the coolant fluid. A subject to be examined is disposed in the bore, which is typically defined as the volume that is surrounded by the main magnet/gradient coil assembly system.

In some magnetic resonance system configurations, a “whole body” radio frequency coil, such as a birdcage coil, a transverse electromagnetic (TEM) coil, or so forth, is employed. The whole body radio frequency coil is typically generally cylindrical, although there is sometimes some deviation from a perfect cylinder, such as in a “D”-shaped whole-body coil having a planar portion aligned with the subject support. As used herein, the term “generally cylindrical” encompasses deviations from a circular cross-section such as in a “D”-shaped whole body coil. A birdcage or TEM coil includes axially oriented conductors, called “rods” or “rungs” that are arranged around the bore, and a generally cylindrical radio frequency shield surrounding the rods or rungs. In a birdcage coil configuration, end rings connect with the rungs at opposite ends of the coil to form electrically conductive “mesh” loops. In a TEM configuration the opposite ends of the rods are connected to the radio frequency shield to define current loops that incorporate the radio frequency shield as a current return path.

Whole body radio frequency coils are driven at a magnetic resonance frequency to generate a radio frequency electromagnetic field, sometimes referred to as the B₁ field, tuned to excite magnetic resonance in the subject. The drive input can have various configurations. In a quadrature driving mode, two drive inputs having a 90° phase offset are used, and the whole body coil is configured to define a volume resonator generating a substantially uniform B₁ field in an examination region portion of the bore volume. In a multi-element transmit mode, the rods or rungs, or selected groups of rods or rungs, are driven independently by different drive inputs, and the rods or rungs (or selected groups of rods or rungs) are configured to be decoupled from each other.

In the multi-element transmit mode, the decoupled and separately driven rods or rungs (or selected groups of rods or rungs) are designed to collectively generate a uniform or other selected B₁ field distribution in the examination region portion of the bore volume. Some multi-element configurations take into account and correct for subject loading effects, such that the generated B₁ field distribution in the examination region portion is uniform with the subject loaded in the examination region.

The use of a whole body radio frequency coil for magnetic resonance excitation has certain advantages. The generally cylindrical whole body radio frequency coil efficiently utilizes bore space. The rods or rungs can be discrete electrically conductive elements mounted on a dielectric former or secured to other components of the magnetic resonance system, or the rods or rungs can be conductive strip lines or transmission lines disposed on a dielectric former. Similarly, the radio frequency shield can take the form of a conductive mesh or screen formed either as a discrete element or as an electrically conductive film disposed on a dielectric former.

However, the radio frequency transmit electronics for driving the whole body radio frequency coil has heretofore been problematic. In a multi-element configuration, N independently driven rods or rungs (or N independently driven groups of rods or rungs) are driven by a corresponding N drive input channels. If there is a known phase relationship between certain transmit channels of the multielement configuration, then the number of drive input channels may be reduced by using suitable radio frequency splitting and phase and/or amplitude transform circuitry. For a quadrature configuration, two drive input channels phase-offset by 90° are used. In some quadrature drive configurations, a single drive input channel is used in conjunction with radio frequency splitting and 90° phase-shifting circuitry.

In summary, there are between 1 and N independent drive input channels. Furthermore, because of the high radio frequency power needed to operate the whole body radio frequency coil in transmit mode, multiple power amplifiers are typically used to implement each drive input channel. Each power amplifier typically includes one or more power MOSFET devices and additional radio frequency circuitry such as matching components, capacitors, radio frequency chokes, or so forth. These high power amplifiers generate substantial heat and require dedicated heat sinking, such as a copper heat sink block with active water cooling lines. Even with suitable heat sinking, the high power MOSFET devices are prone to occasional failure, especially in clinical magnetic resonance settings that accommodate a high throughput of human imaging subjects.

In a typical arrangement, the power amplifiers are mounted in an electronics rack or other location proximate to the main magnet/gradient coil assembly, and coaxial cabling connects the power amplifiers with the whole body radio frequency coil. The power amplifiers are located outside of the main magnet/gradient coil assembly and bore space, and hence are accessible for replacement of failed amplifier units. Externally mounted power amplifiers are also easily configured with water cooling.

However, these existing arrangements have substantial disadvantages. The coaxial cabling connecting the amplifiers with the whole body radio frequency coil should be designed to ensure that radio frequency power of the correct amplitude and phase is applied to each drive input channel of the whole body radio frequency coil. This places stringent constraints on coaxial cable length, and additionally radio frequency chokes are inserted in the coaxial cabling to suppress undesired current flow. Phase or amplitude errors can adversely impact the B₁ field distribution, and in multi-element configurations can introduce parasitic coupling of nominally decoupled rods or rungs leading to further degradation of the B₁ field distribution.

The power amplifiers rack and associated coaxial cabling should be well shielded. Gaps or other imperfections in the shielding can result in radio frequency interference that can adversely affect acquired magnetic resonance data and/or can interfere with other electronics. Still further, the power amplifiers rack and associated coaxial cabling occupy valuable space in the magnetic resonance facility, and the cabling can interfere with the free movement of the radiologist or other medical personnel. The active water cooling system of the power amplifiers rack is yet another disadvantage, as this additional mechanical system is prone to occasional failure.

The following provides new and improved apparatuses and methods which overcome the above-referenced problems and others.

In accordance with one disclosed aspect, a magnetic field gradient coil assembly comprises: a structural former; one or more magnetic field gradient coils disposed on or in the structural former; cooling conduits disposed on or in the structural former and configured to flow cooling fluid for removing heat generated by the one or more magnetic field gradient coils; and a radio frequency power amplifier disposed on or in the structural former.

In accordance with another disclosed aspect, a magnetic resonance component assembly comprises: a generally cylindrical magnetic field gradient coil assembly including a generally cylindrical dielectric former that defines an axial direction and one or more magnetic field gradient coils disposed on or in the generally cylindrical dielectric former, cooling conduits disposed on or in the generally cylindrical dielectric former being configured to flow cooling fluid for removing heat generated by the one or more magnetic field gradient coils; a generally cylindrical radio frequency coil or coil array disposed coaxially with the generally cylindrical magnetic field gradient coil assembly; and a plurality of radio frequency power amplifiers disposed on or in the generally cylindrical dielectric former and operatively connected to drive the generally cylindrical radio frequency coil or coil array.

One advantage resides in a more compact magnetic resonance system.

Another advantage resides in reduced transmission lengths for high power radio frequency signals, and concomitant reduction in the likelihood of generating radio frequency interference.

Another advantage resides in reduced radio frequency cabling lengths.

Another advantage resides in more precise amplitude and phase control in driving input channels of a whole body radio frequency coil.

Another advantage resides in a reduction in the number of active fluid cooling systems employed in a magnetic resonance facility.

Further advantages will be apparent to those of ordinary skill in the art upon reading and understand the following detailed description.

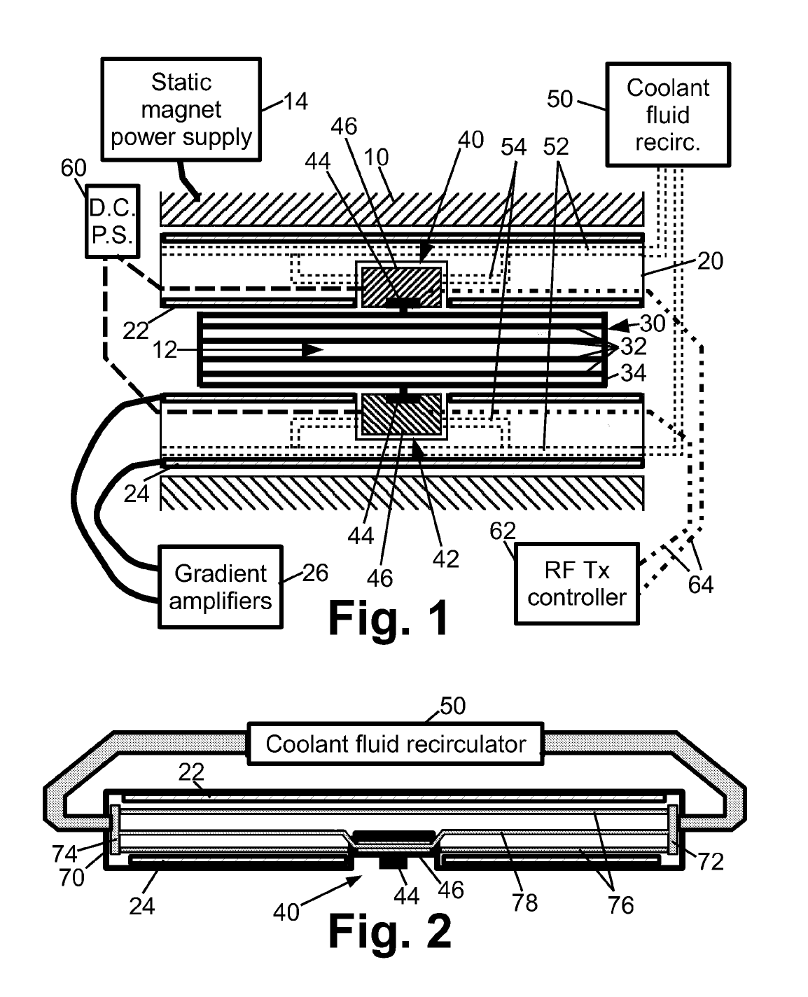

FIG. 1 diagrammatically shows a magnetic resonance system including a main magnet, radio frequency coil, and a magnetic field gradient coil assembly with integrated active radio frequency power amplifiers.

FIG. 2 diagrammatically shows a magnetic resonance component assembly including a magnetic field gradient coil assembly with at least one integrated active radio frequency power amplifier.

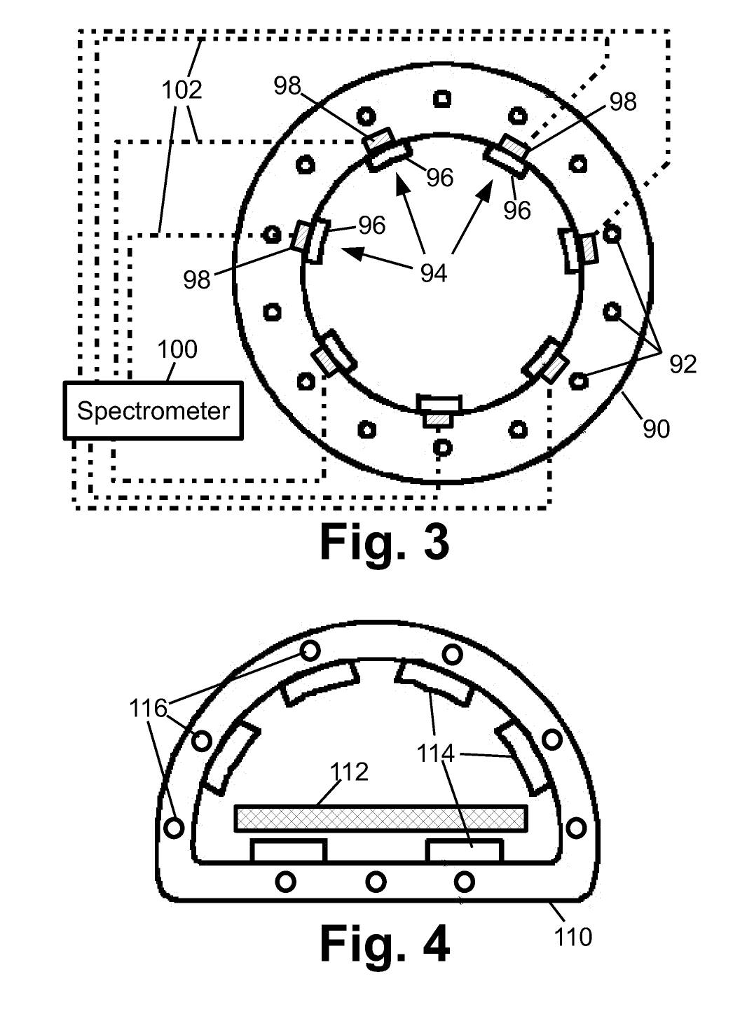

FIG. 3 diagrammatically shows an end view of a magnetic resonance component assembly including a cylindrical magnetic field gradient coil assembly with water cooling and a plurality of integrated active radio frequency power amplifiers.

FIG. 4 diagrammatically shows an end view of a magnetic resonance component assembly including a generally cylindrical magnetic field gradient coil assembly having a “D”-shape, with water cooling and a plurality of integrated active radio frequency power amplifiers.

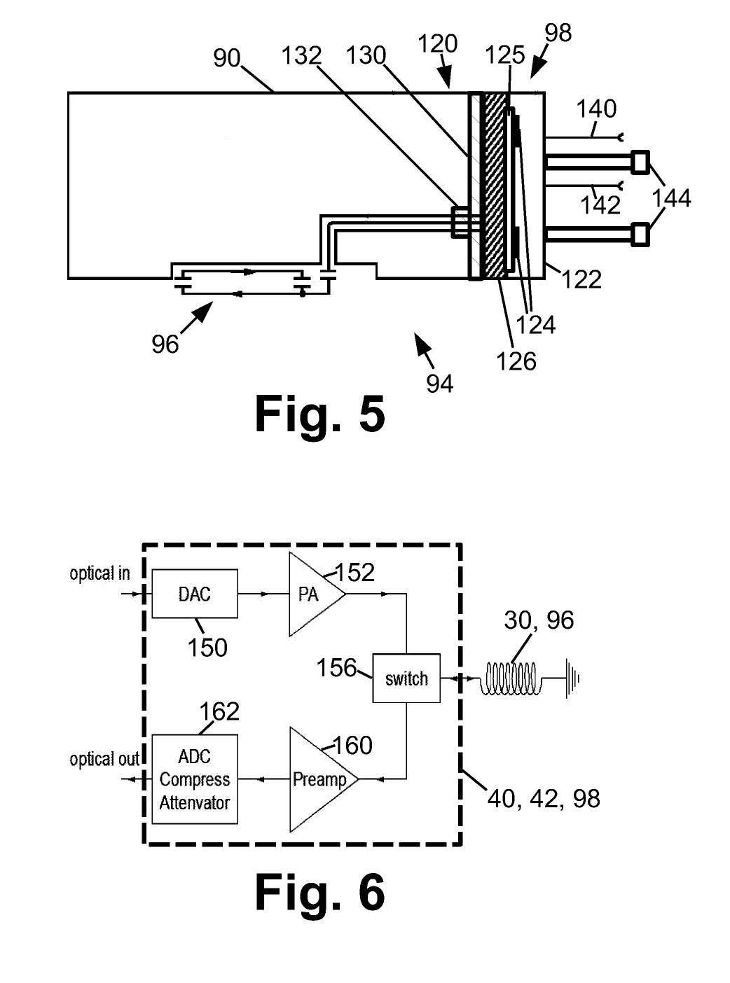

FIG. 5 diagrammatically shows a magnetic resonance component assembly including a magnetic field gradient coil assembly with at least one end-mounted modular integrated active radio frequency power amplifier.

FIG. 6 diagrammatically shows a schematic for an integrated active radio frequency transmit/receive amplifier.

Corresponding reference numerals when used in the various figures represent corresponding elements in the figures.

With reference to FIG. 1, a magnetic resonance system includes a generally cylindrical main magnet 10 configured to generate a static (B₀) magnetic field in a generally cylindrical bore region 12 defined by the magnet 10. The main magnet 10 is driven by a static magnet power supply 14, and may be a resistive main magnet or a superconducting main magnet. A gradient coil assembly includes a structural former 20, which is preferably a generally cylindrical dielectric former, that supports (i) one or more primary magnetic field gradient coils 22 on or proximate to an inner surface, and (ii) one or more shield magnetic field gradient coils 24 on or proximate to an outer surface. The gradient coils 22, 24 are driven by gradient amplifiers 26 to superimpose selected magnetic field gradients on the static (B₀) magnetic field. Such gradients are used in various ways known in the art, such as to spatially encode magnetic resonance, to spoil magnetic resonance, to spatially limit magnetic resonance excitation to a selected slice or other geometrical region, or so forth.

The magnetic resonance system further includes a whole-body radio frequency coil 30. The illustrated radio frequency coil is configured as a birdcage coil including rungs 32 and end rings 34, and defines a volume resonator when operated in quadrature mode. An rf-confining shield (not shown) typically surrounds the birdcage coil. In other embodiments, the whole-body radio frequency coil may be a transverse electromagnetic (TEM) coil in which the end rings are omitted and the rungs (typically referred to as “rods” in the TEM configuration) are connected at their ends to the radio frequency (rf) shield to define current return paths. The TEM coil also defines a volume resonator. In yet other embodiments, the rods or rungs, or selected groups of rods or rungs, are electrically decoupled and are driven independently to define a transmit array.

The magnetic field gradient coil assembly 20, 22, 24 illustrated in FIG. 1 is a split gradient coil having a gap or recess at about an axial center of the generally cylindrical structural former 20. Some suitable split gradient coils are described, for example, in the International patent application WO 2008/122899 A1 published Oct. 16, 2008. The illustrated dielectric former 20 has a gap in the form of an annular recess that does not completely split the former. In other embodiments the gap may completely split the dielectric former into two halves that are secured together by a brace extending across the gap, as also disclosed in WO 2008/122899 A1.

The gap of the illustrated split gradient coil assembly 20, 22, 24 receives one or more radio frequency power amplifiers, such as illustrated power amplifiers 40, 42. Each power amplifier includes one or more electrical power amplifier devices, such as one or more power MOSFET transistors 44, that are configured to drive the radio frequency coil 30 or selected transmitter array portions thereof. A heat sink 46 of copper or another heat sinking material or material configuration provides heat sinking for the MOSFET transistor or transistors 44. Although not shown in FIG. 1, the MOSFET transistors 44 are typically mounted on a printed circuit board (PCB) that includes electrical connection circuitry and optionally other electrical components such as an rf choke, PIN diode switches, filter circuits, detuning circuitry, or so forth interconnected to define a suitable power amplifier circuit configuration for driving a transmit radio frequency coil. In some embodiments, a metal core printed circuit board (MCPCB) is used to provide efficient thermal communication between the circuit components (such as the illustrated MOSFET power transistor 44) and the heat sink 46. The power amplifiers 40, 42 are optionally shielded (not shown) to suppress radio frequency interference, especially if the power amplifier has a class D or E configuration employing switching amplifiers. The power amplifiers 40, 42 can be secured in the gap of the structural former 20 in various ways, such as by mechanical springs, a welded connection, or so forth. If mechanical springs or another readily detachable connection is used, then the power amplifiers 40, 42 are easily removable for repair or replacement.

Placing the power amplifiers 40, 42 on or in the gradient coil assembly 20, 22, 24 has certain advantages as compared with the conventional arrangement in which the power amplifiers are located externally, for example in an electronics rack. For example, the coupling distance for injecting the radio frequency power generated by the gradient coil assembly-mounted power amplifiers 40, 42 into the whole-body radio frequency coil 30 is shortened. In FIG. 1, the power amplifiers 40, 42 couple into the whole-body radio frequency coil 30 at the midpoint of proximate rungs 32, for example by connecting the radio frequency power output terminals over a capacitor inserted in the rung.

Another advantage of mounting the power amplifiers 40, 42 on or in the gradient coil assembly is that the water cooling of the gradient coil assembly can be tapped or extended to provide water cooling for the heat sinks 46 of the power amplifiers 40, 42. The gradient coil assembly 20, 22, 24 is actively cooled by a coolant fluid recirculator 50 that flows water through copper tubing 52 (or another suitable coolant fluid conduit) passing through the structural former 20. Instead of using water as the coolant fluid, Freon™, liquid nitrogen, forced air, or another coolant fluid is also contemplated. Additional copper piping 54 diverts some coolant fluid to flow proximate to or through the heat sinks 46 for removing heat generated by the radio frequency power amplifiers 40, 42. Note that in FIG. 1 the copper piping flowing the coolant fluid is shown using dashed lines. It is also to be appreciated that the coolant fluid recirculator 50 can optionally be replaced by an open arrangement in which the coolant fluid is not recirculated. For example, in a forced air system a compressor may inject forced air into the coolant conduits passing through the dielectric former of the gradient coil, and the outlet of the conduits may be connected to a suitable exhaust.

Yet another advantage of mounting the power amplifiers 40, 42 on or in the gradient coil assembly is that the potential for radio frequency interference (rfi) is reduced. In the embodiment illustrated in FIG. 1, the power amplifiers 40, 42 are powered by a direct current (d.c.) power source 60. Alternatively, a low frequency power source such as 50 Hz or 60 Hz alternating current (a.c.) can be used. In FIG. 1, cabling connecting the power source 60 with the power amplifiers 40, 42 is illustrated using long-dashed lines. The power source 60 produces no a.c. component (neglecting any ripple currents or so forth), while a 50 Hz or 60 Hz a.c. power source produces rfi, if at all, only at low frequency harmonics well away from the magnetic resonance frequency. Control for the power amplifiers 40, 42 is suitably supplied using a radio frequency transmit controller 62, which optionally may be a digital radio frequency transmit controller, that outputs an optical control signal that is conveyed to the power amplifiers 40, 42 via optical fibers 64 (illustrated in FIG. 1 using dot-dot-dash lines). These optical signals advantageously do not produce rfi.

Still yet other advantages of mounting the power amplifiers 40, 42 on or in the gradient coil assembly include: a more compact magnetic resonance system; elimination of rf cabling between electronics racks and the magnetic resonance system; and more precise amplitude and phase control in driving input channels of the whole body radio frequency coil 40 due to the shorter, well-defined rf cables path lengths.

A disadvantage of the arrangement of FIG. 1 is that the coolant lines 54 for cooling the power amplifiers 40, 42 is tapped off of coolant lines 52 that cool the gradient coils 22, 24. This arrangement has the potential to produce temperature gradients across the gradient coils 22, 24.

With reference to FIG. 2, a modified dielectric structural former 70 has fluid inlet and outlet manifolds 72, 74 that deliver coolant fluid into and out of coolant paths 76 for cooling the gradient coils 22, 24 and into separate coolant paths 78 for cooling the heat sinks 46. In the embodiments of FIGS. 1 and 2 the cooling conduits 54, 78 further configured to remove heat generated by the radio frequency power amplifier pass through the heat sink 46. However, it is also contemplated in other embodiments for the amplifier coolant lines to pass proximate to, but not through, the heat sinks, for removing heat generated by the radio frequency power amplifier. In such embodiments, the coolant lines should be sufficiently proximate to the heat sink to provide heat transfer from the heat sink to the coolant lines effective for removing heat generated by the power amplifier.

With reference to FIG. 3, in some embodiments the whole body radio frequency coil is a multi-element coil array. FIG. 3 shows an end view of a cylindrical dielectric structural former 90 that supports gradient coils (not shown in FIG. 3) cooled by coolant lines 92. A transmit coil array includes seven active transmit coil assemblies 94 that are decoupled from each other. Each active transmit coil assembly 94 includes a rod or rung 96 (viewed “on-end” in FIG. 3) and an integrated power amplifier 98 mounted on an end of the cylindrical dielectric former 90 and operatively coupled to drive the rod or rung 96 in a transmit mode. Suitable coolant fluid taps or designated coolant fluid lines (not shown) in the dielectric structural former 90 are configured to flow cooling fluid proximate to or through heat sinks of the power amplifiers 98 for removing heat generated by the radio frequency power amplifier 98. A spectrometer 100 independently drives the power amplifier 98 of each of the active transmit coil assemblies 94 via optical fibers 102 (shown diagrammatically in FIG. 3 using dot-dot-dash lines) so as to operate each active transmit coil assembly 94 at a selected rf amplitude and phase, frequency and arbitrary complex rf pulse form. The B₁ fields generated by the independently driven active transmit coil assemblies 94 combine in a superposition manner (that is, the fields are superimposed on one another) to generate a desired B₁ field distribution in the bore. Instead of separately and independently driving each rod or rung as shown in FIG. 3, it is also contemplated to separately and independently drive selected groups of rods or rungs defining channels of a multi-element coil array.

With reference to FIG. 4, it is to be appreciated that the generally cylindrical gradient coil assembly and the generally cylindrical radio frequency coil can have some substantial deviation from a perfectly circular cross section. In the embodiment of FIG. 4, a generally cylindrical dielectric structural former 110 has a “D” shape as shown by the on-end view of FIG. 4. The flat portion of the “D” shape is designed for alignment with a planar subject support 112 so that the gradient coils (not shown in FIG. 4) supported by the flat portion of the “D” shape are positioned close to the subject on the planar subject support 112. Rungs or rods 114 of a generally cylindrical whole body radio frequency coil also conform to the “D” shape of the gradient coil assembly. Fluid cooling lines 116 disposed in or on the dielectric structural former 110 provide cooling for the gradient coils and for integrated power amplifiers (not shown in FIG. 4) that drive the rods or rungs 114 in a quadrature, multi-element, or other transmit drive configuration.

With reference to FIG. 5, a suitable arrangement for an illustrative one of the active transmit coil assemblies 94 is shown. In this embodiment, the integrated power amplifier 98 is mounted on an axial end 120 of the cylindrical dielectric former 90. The power amplifier 98 includes a housing 122, which is optionally made of copper or another suitable shielding material, that houses two illustrated MOSFET power transistors 124 disposed on a printed circuit board (PCB) 125 that has a metal core (not shown) or is otherwise in thermal communication with a heat sink 126. The power amplifier 98 is configured as a removable module that connects with the axial end 120 of the structural former 90 via an illustrated socket 130 including an electrical connector 132 for connecting with the rod or rung 96 (or, in other embodiments, with a group of rods or with a complete birdcage or TEM coil) that is driven by the power amplifier 98. The socket 130 can employ various retention mechanisms for securing the modular power amplifier 98 to the end 130 of the dielectric structural former 90, such as a spring-biased connection, a snap connection, a bayonet connection, or so forth. The modular power amplifier 98 has an optical radio frequency control input 140 and a d.c. power input 142. Inlet and outlet coolant lines 144 are suitably connected with the same coolant fluid recirculator, air compressor, or other coolant fluid source (not shown in FIGS. 3 and 5) that inputs coolant fluid into the coolant lines 92 disposed in or on the structural former 90.

In FIG. 5, the power amplifier 98 is modular and readily removable. Optionally, the whole body radio frequency coil or coil array 96 is also a modular unit that can be inserted into the bore 12 of the magnetic resonance scanner. For example, the coil array elements 96 may be mounted on a generally cylindrical dielectric former that is sized to insert coaxially inside the structural former 90 of the gradient coil assembly. In other embodiments, both the power amplifier and the radio frequency coil or coil array elements are contemplated to be integrated as a singular module that is readily removable. For example, the end-mounted power amplifiers 98 can be integrated with head coil elements to form a removable head coil that can be removably mounted at one end of the generally cylindrical structural former 90 of the gradient coil assembly.

In FIG. 3, the modular power amplifiers 98 are all mounted on the same axial end of the generally cylindrical structural former 90. However, in other embodiments it is contemplated to distribute end-mounted power amplifiers at both axial ends of a generally cylindrical structural former. Such a “double-ended” distribution may, for example, more conveniently divide up the mass, electrical connections, coolant fluid connections, or other aspects of the power amplifiers.

With reference to FIG. 6, although transmit aspects have been described, it is to be appreciated that the illustrated whole body radio frequency coils 30, 94, 114 can also be configured to serve as receive coils. For example, the illustrated power amplifiers 40, 42, 98 can optionally incorporate receive circuitry and suitable switching circuitry so as to configure the whole body radio frequency coils 30, 94, 114 as transmit/receive (T/R) coils. FIG. 6 shows a suitable functional diagram of one of the power amplifiers 40, 42, 98 configured for T/R operation. The transmit components include a photodiode or other transducer (not shown) that receives the optical radio frequency control input, an optional digital-to-analog converter (DAC) 150 (appropriately included if the rf transmit controller 62 or spectrometer 100 is a digital controller outputting the optical radio frequency control signal in digital form) driving power amplification circuitry 152 which includes, for example, one or more MOSFET transistors 44, 124 as illustrated in other FIGURES. During the transmit phase, a switch 156 connects the transmit chain 150, 152 to the whole body radio frequency coil 30 or coil array element 96. On the other hand, during the receive phase, the switch 156 connects the whole body radio frequency coil 30 or coil array element 96 with a preamplifier 160 that amplifies the magnetic resonance signal received by the coil 30 or coil array element 96. Additional signal conditioning circuitry 162 is optionally provided to, for example, perform analog-to-digital conversion (ADC), compress the signal for more efficient transmission, or so forth. The amplified and optionally further conditioned magnetic resonance signal is ported off of the power amplifiers 40, 42, 98, for example as an optical output generated by a laser diode or other optoelectronic light source (not shown).

While optical radio frequency control inputs coupled with optical fibers 64, 102 are illustrated herein, it is to be understood that other types of nonelectrical inputs and input connections can also be used, such as infrared inputs transmitted via the air. Moreover, the use of electrical radio frequency input delivered by coaxial, triaxial, or other suitably shielded electrical cables is also contemplated.

The radio frequency excitation and receive elements illustrated herein can be configured to operate at the proton or ¹H magnetic resonance frequency, or can be configured to operate at another magnetic resonance frequency. For spectroscopy applications, it is also contemplated for different elements 96 of the active coil array 94 to operate at different magnetic frequencies. For example, some (e.g., one-half) of the coil elements 96 may be tuned to operate at the ¹H magnetic resonance frequency while others (e.g., the other half) of the coil elements 96 may be tuned to operate at the ¹³C magnetic resonance frequency or another magnetic resonance frequency. Since in the embodiment of FIGS. 3 and 5 each coil element 96 is independently driven by a corresponding power amplifier 98, it is straightforward to implement such multi-frequency operation so long as the elements are tuned to ensure suitable decoupling.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof.

1. A magnetic field gradient coil assembly comprising:
a structural former;
one or more magnetic field gradient coils disposed on or in the structural former;
cooling conduits disposed on or in the structural former and configured to flow cooling fluid for removing heat generated by the one or more magnetic field gradient coils; and
a radio frequency power amplifier disposed on or in the structural former.

2. The magnetic field gradient coil assembly as set forth in claim 1, wherein the radio frequency power amplifier includes a heat sink and cooling conduits disposed on or in the structural former are further configured to flow cooling fluid proximate to or through the heat sink for removing heat generated by the radio frequency power amplifier.

3. The magnetic field gradient coil assembly as set forth in claim 1, wherein the cooling conduits disposed on or in the structural former and the radio frequency power amplifier both receive cooling fluid from a common cooling fluid source.

4. The magnetic field gradient coil assembly as set forth in claim 1, wherein the structural former comprises a generally cylindrical dielectric former.

5. The magnetic field gradient coil assembly as set forth in claim 1, wherein the structural former is generally cylindrical and the radio frequency power amplifier is supported in a gap or recess of the generally cylindrical dielectric former at about an axial center of the generally cylindrical structural former.

6. The magnetic field gradient coil assembly as set forth in claim 1, wherein the structural former is generally cylindrical and the radio frequency power amplifier is supported by the generally cylindrical structural former at an axial end of the generally cylindrical structural former.

7. The magnetic field gradient coil assembly as set forth in claim 1, wherein the radio frequency power amplifier comprises:
a plurality of radio frequency power amplifiers disposed on or in the structural former.

8. The magnetic field gradient coil assembly as set forth in claim 1, wherein the radio frequency power amplifier is configured to drive a whole body radio frequency coil or whole body coil array at a magnetic resonance frequency to excite magnetic resonance.

9. The magnetic field gradient coil assembly as set forth in claim 1, wherein the radio frequency power amplifier is configured as a replaceable module that is removable as a module from the magnetic field gradient coil assembly.

10. A magnetic resonance component assembly comprising:
a generally cylindrical magnetic field gradient coil assembly including a generally cylindrical dielectric former that defines an axial direction and one or more magnetic field gradient coils disposed on or in the generally cylindrical dielectric former, cooling conduits disposed on or in the generally cylindrical dielectric former being configured to flow cooling fluid for removing heat generated by the one or more magnetic field gradient coils;
a generally cylindrical radio frequency coil or coil array disposed coaxially with the generally cylindrical magnetic field gradient coil assembly; and
a plurality of radio frequency power amplifiers disposed on or in the generally cylindrical dielectric former and operatively connected to drive the generally cylindrical radio frequency coil or coil array.

11. The magnetic resonance component assembly as set forth in claim 10, wherein the radio frequency power amplifiers include heat sinks, and cooling conduits disposed on or in the generally cylindrical dielectric former are configured to flow cooling fluid proximate to or through the heat sinks for removing heat generated by the radio frequency power amplifiers.

12. The magnetic resonance component assembly as set forth in claim 10, further comprising:
a coolant fluid source that inputs coolant fluid to both (i) the cooling conduits disposed on or in the generally cylindrical dielectric former and (ii) cooling fluid inlets that flow coolant fluid into the radio frequency power amplifiers to remove heat generated by the radio frequency power amplifiers.

13. The magnetic resonance component assembly as set forth in claim 10, wherein the radio frequency power amplifiers are supported in one or more gaps or recesses of the generally cylindrical dielectric former at about an axial center of the generally cylindrical dielectric former.

14. The magnetic resonance component assembly as set forth in claim 13, wherein the radio frequency power amplifiers operatively connect with the generally cylindrical radio frequency coil at about an axial center of the generally cylindrical radio frequency coil to drive the generally cylindrical radio frequency coil.

15. The magnetic resonance component assembly as set forth in claim 10, wherein the radio frequency power amplifiers are supported by the generally cylindrical dielectric former at one or both axial ends of the generally cylindrical dielectric former.

16. The magnetic resonance component assembly as set forth in claim 15, wherein all the radio frequency power amplifiers are supported by the generally cylindrical dielectric former at the same axial end of the generally cylindrical dielectric former.

17. The magnetic resonance component assembly as set forth in claim 10, wherein the radio frequency power amplifiers are operatively connected to drive the generally cylindrical radio frequency coil in a quadrature mode.

18. The magnetic resonance component assembly as set forth in claim 10, wherein the radio frequency power amplifiers are operatively connected to independently drive decoupled elements of the generally cylindrical radio frequency coil array.

19. The magnetic resonance component assembly as set forth in claim 18, wherein the radio frequency power amplifiers are operatively connected to independently drive different decoupled elements at different magnetic resonance frequencies.

20. The magnetic resonance component assembly as set forth in claim 10, wherein the generally cylindrical radio frequency coil or coil array is distributed along an axial direction of the generally cylindrical magnetic field gradient coil assembly.

21. The magnetic resonance component assembly as set forth in claim 10, wherein the generally cylindrical radio frequency coil or coil array is configured as an insertable module that is insertable into the generally cylindrical dielectric former of the generally cylindrical magnetic field gradient coil assembly.
